(19) United States
(12) Patent Application Publication
(10) Pub. No.: US 2026/0282364 A1
(43) Pub. Date: Sep. 17, 2026

(54) COMPACT BITCELL

(71) Applicant: GlobalFoundries Singapore Pte. Ltd., Singapore (SG)

(72) Inventors: Yongshun Sun, Singapore (SG); Eng Huat Toh, Singapore (SG); Shyue Seng Tan, Singapore (SG)

(21) Appl. No.: 19/078,591

(22) Filed: Mar. 13, 2025

(51) Int. Cl. H10B 43/30; H10D 30/69; H10D 64/68

(52) U.S. Cl. CPC H10B 43/30; H10D 30/696; H10D 64/693

(57) ABSTRACT

The present disclosure relates to semiconductor structures and, more particularly, to bitcell structures and methods of manufacture. The structure includes: a semiconductor substrate; a plurality of memory gates isolated from the semiconductor substrate by a stack of insulator materials; and a select gate embedded within the semiconductor substrate and shared with the plurality of memory gates.

### BACKGROUND

The present disclosure relates to semiconductor structures and, more particularly, to bitcell structures and methods of manufacture.

A silicon-oxide-nitride-oxide-silicon (SONOS) bitcell is a nonvolatile memory transistor that stores one bit of data. The SONOS bitcell consists of two transistors, a SONOS (e.g., control or memory gate) and a MOS (select gate). The SONOS technology is a good replacement for floating gate nonvolatile memory because of its low voltage operation and simple bitcell structure. The SONOS technology may be used in many devices, including bank cards, SIM cards, and microcontrollers as examples.

### SUMMARY

In an aspect of the disclosure, a structure comprises: a semiconductor substrate; a plurality of memory gates isolated from the semiconductor substrate by a stack of insulator materials; and a select gate embedded within the semiconductor substrate and shared with the plurality of memory gates.

In an aspect of the disclosure, a structure comprises: a semiconductor substrate comprising diffusion regions; a plurality of memory gates between the diffusion regions and isolated from the semiconductor substrate by a stack of insulator materials; and a select gate shared amongst the plurality of memory gates and within the semiconductor substrate.

In an aspect of the disclosure, a method comprises: forming a plurality of memory gates isolated from a semiconductor substrate by a stack of insulator materials; and forming a select gate embedded within the semiconductor substrate and shared with the plurality of memory gates.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a structure and respective fabrication processes in accordance with aspects of the present disclosure.

FIGS. 2-7 show alternative structures in accordance with aspects of the present disclosure.

### DETAILED DESCRIPTION

The present disclosure relates to semiconductor structures and, more particularly, to bitcell structures and methods of manufacture. More specifically, the bitcell may be a compact silicon-oxide-nitride-oxide-silicon (SONOS) bitcell. Advantageously, the SONOS bitcell may comprise a dual bit layout structure with a reduced cell size, and can be configured as a multi-bit SONOS memory with a shared single select gate under the surface of the semiconductor substrate.

The bitcell of the present disclosure can be manufactured in a number of ways using a number of different tools. In general, though, the methodologies and tools are used to form structures with dimensions in the micrometer and nanometer scale. The methodologies, i.e., technologies, employed to manufacture the bitcell of the present disclosure have been adopted from integrated circuit (IC) technology. For example, the structures are built on wafers and are realized in films of material patterned by photolithographic processes on the top of a wafer. In particular, the fabrication of the bitcell uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

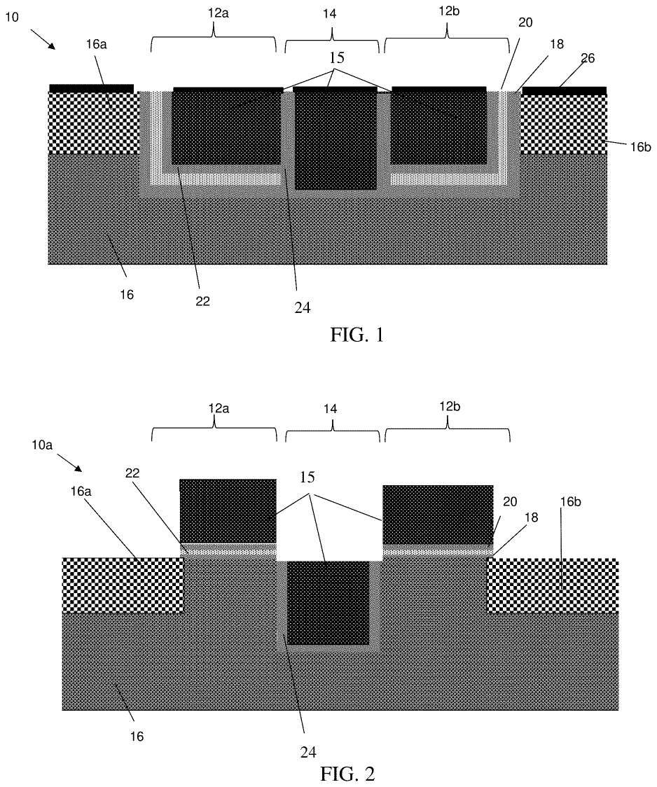

FIG. 1 shows a structure and respective fabrication processes in accordance with aspects of the present disclosure. The structure 10 includes a first memory gate 12a, a second memory gate 12b and a select gate 14, each of which are embedded within a semiconductor substrate 16. In embodiments, the select gate 14 is sandwiched between the first memory gate 12a and the second memory gate 12b. Accordingly, in this configuration, the select gate 14, the first memory gate 12a and the second memory gate 12b may each be below the surface of the semiconductor substrate 16 and may be laterally disposed (and aligned) with respect to one another. Also, in this and the other embodiments described herein, the select gate 14 is shared between both the first memory gate 12a and the second memory gate 12b.

The semiconductor substrate 16 may be bulk semiconductor material or semiconductor-on-insulator (SOI) technology. As is understood in the art, the SOI technology includes a handle substrate, a buried insulator layer (i.e., substrate) and a top semiconductor layer. In any scenario, the handle substrate, the top semiconductor layer and/or the bulk semiconductor material may be any suitable semiconductor material including, but not limited to, Si, SiGe, SiGeC, SiC, GaAs, InAs, InP, and other III/V or II/VI compound semiconductors. The semiconductor material may comprise any suitable single crystallographic orientation (e.g., a (100), (110), (111), or (001) crystallographic orientation).

Still referring to FIG. 1, diffusion regions 16a, 16b may be provided adjacent to (e.g., sides of) the first memory gate 12a and the second memory gate 12b. In more specific embodiments, the diffusion regions 16a, 16b may be provided in the semiconductor material 16 adjacent to outer sides of the first memory gate 12a and the second memory gate 12b. The diffusion region 16a may be a source-line implant and the diffusion region 16b may be a bit-line implant. The diffusion regions 16a, 16b may be n+implants; whereas the semiconductor material 16 may p-doped to form a p-well implant underneath the diffusion regions 16a, 16b and the gate structures 12a, 12b, 14.

The p-well and the diffusion regions 16a, 16b may be formed by introducing a dopant by, for example, ion implantation processes. In embodiments, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The p-well is doped with p-type dopants, e.g., Boron (B), and the diffusion regions 16a, 16b may be doped with n-type dopants, e.g., Arsenic (As), Phosphorus (P) and Antimony (Sb), among other suitable examples.

The first memory gate 12a, the second memory gate 12b and the select gate 14 are embedded within the semiconductor substrate 16, with the first memory gate 12a, second memory gate 12b and select gate 14 isolated from one another and the semiconductor material 16 by insulator material(s). For example, both the first memory gate 12a and the second memory gate 12b may include a work function material 15, e.g., polysilicon, isolated from the semiconductor substrate 16, e.g., on the bottom and outer edges of the gates 12a, 12b, by insulator materials 18, 20, 22. In embodiments, insulator material 18 may be oxide material, insulator material 20 may be nitride material and insulator material 22 may be oxide material. On the other hand, the select gate 14 may include work function material 15, e.g., polysilicon, isolated from the semiconductor material 16 and both the first and second memory gates 12a, 12b by insulator material 24, e.g., oxide In this way, it is now possible to create a compact dual bit SONOS memory cell with embedded memory gates 12a, 12b and a shared select gate 14 to achieve reduced cell size with multi-bits operation. Also, in operation, the bitcells can be programmed by a source side injection and in an erase operation, the bitcells can be erased using Fowler-Nordheim tunneling (F-N tunneling).

The first memory gate 12a, second memory gate 12b and select gate 14 may be formed in a trench of the semiconductor substrate 16. The trench can be formed by conventional lithography, etching and deposition methods known to those of skill in the art. For example, a resist formed over the semiconductor substrate 16 is exposed to energy (light) and developed utilizing a conventional resist developer to form a pattern (opening). An etching process with a selective chemistry, e.g., reactive ion etching (RIE), will be used to transfer the pattern from the patterned photoresist layer to the semiconductor substrate 16 to form the trench in the semiconductor substrate 16 through the openings of the resist. Following the resist removal by a conventional oxygen ashing process or other known stripants, the insulator materials 18, 20, 22, 24 and work function material 15, e.g., polysilicon, can be deposited by any conventional deposition processes, e.g., chemical vapor deposition (CVD) processes, and respective patterning processes as required to achieve the structure 10 of FIG. 1. Any residual material on the surface of the semiconductor substrate 16 can be removed by conventional chemical mechanical polishing (CMP) processes.

As should further be understood by those of skill in the art, a silicide process may be used to form silicide contacts 26 on the polysilicon material 15 and the diffusion regions 16a, 16b. The silicide process begins with deposition of a thin transition metal layer, e.g., nickel, cobalt or titanium, over the fully formed and patterned polysilicon material 15 and the diffusion regions 16a, 16b. After deposition of the material, the structure is heated allowing the transition metal to react with exposed silicon (or other semiconductor material as described herein) in the active regions of the semiconductor device (e.g., source, drain, gate contact region) forming a low-resistance transition metal silicide. Following the reaction, any remaining transition metal is removed by chemical etching, leaving silicide contacts 26 in the active regions of the device. It should be understood by those of skill in the art that silicide contacts will not be required on the devices when a gate structure is composed of a metal material.

FIGS. 2-7 show alternative structures in accordance with aspects of the present disclosure. In FIG. 2, the structure 10a includes the first memory gate 12a and the second memory gate 12b on a surface of the semiconductor substrate 16, with the select gate 14 embedded within the semiconductor substrate 16. In this embodiment, the select gate 14 may be below and between the first memory gate 12a and the second memory gate 12b, such that the select gate 14 is vertically disposed with respect to the first memory gate 12a and the second memory gate 12b. Also, in this configuration, the first memory gate 12a and the second memory gate 12b are laterally disposed with respect to one another. Moreover, in this configuration, it is now possible to avoid high voltage stress on an inter-poly oxide as the select gage 14 is below the surface of the semiconductor substrate 16 and the memory gates 12a, 12b are above the semiconductor substrate 16.

In this embodiment, the first memory gate 12a and the second memory gate 12b may be isolated, e.g., separated, from the semiconductor substrate 16 by the insulator materials 18, 20, 22 (e.g., between the memory gates 12a, 12b and the semiconductor substrate 16). The select gate 16 may be formed within a trench of the semiconductor substrate 16 and isolated from the semiconductor substrate 16 by the insulator material 24, e.g., oxide on sidewalls of the trench. The remaining features of the structure 10a are similar to the structure 10 of FIG. 1 such that no further explanation is required for a complete understanding of the present disclosure.

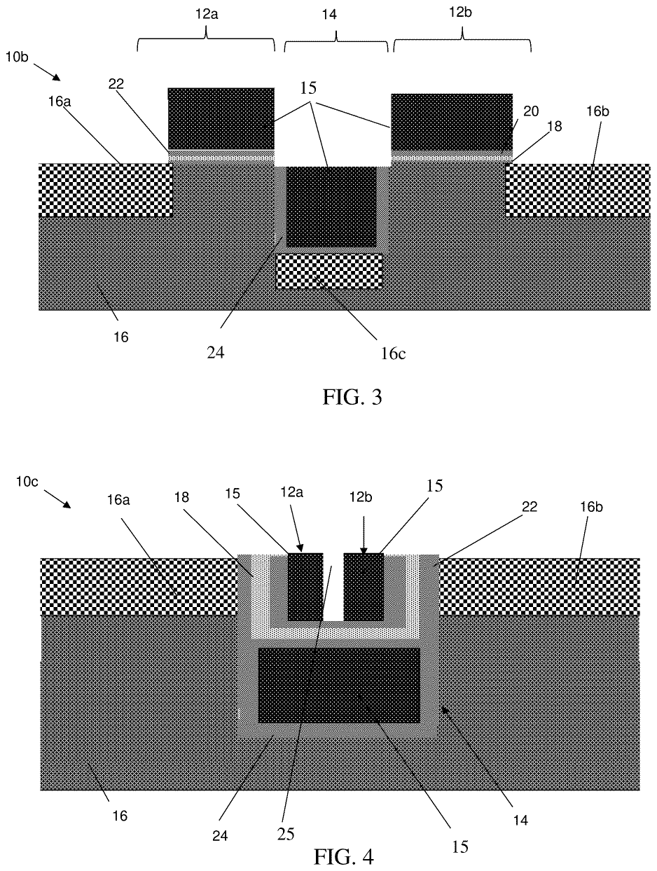

In FIG. 3, the structure 10b includes a diffusion region 16c provided underneath the select gate 14 (in the same configuration as shown in FIG. 2). The diffusion region 16c may be an n+diffusion region within the semiconductor substrate 16, which is separated from the work function material 15, e.g., polysilicon, of the select gate 14 by the insulator material 24. The remaining features of the structure 10b are similar to the structure 10a of FIG. 2 such that no further explanation is required for a complete understanding of the present disclosure.

In FIG. 4, the structure 10c includes the first memory gate 12a and the second memory gate 12b over the select gate 14, all of which are embedded within the semiconductor substrate 16. For example, in this embodiment, the first memory gate 12a, the second memory gate 12b and the select gate 14 may be provided with a trench formed in the semiconductor substrate 16, with the first memory gate 12a and the second memory gate 12b above the select gate 14. In this way, the select gate 14 may be below the first memory gate 12a and the second memory gate 12b such that the select gate 14 is vertically disposed from the first and second memory gates 12a, 12b, and the first memory gate 12a is laterally disposed with respect to the second memory gate 12b. In even more specific embodiments, the select gate 14 and the first and second memory gates 12a, 12b are in vertical alignment.

Still referring to FIG. 4, in this embodiment, the work function material 15, e.g., polysilicon material, of the first memory gate 12a and the second memory gate 12b may be separated from one another by an airgap 25 or other insulator material. Also, a width of the select gate 14 may be the same as a combination of the first memory gate 12a, the second memory gate 12b and the airgap 25 (which separates the first memory gate 12a and the second memory gate 12b). Moreover, the diffusion regions 16a, 16b may be provided adjacent to, e.g., on outer sides, the first memory gate 12a and the second memory gate 12b. The insulator materials 18, 20, 22 may be provided between the diffusion regions 16a, 16b, in addition to underneath the gate structures 12a, 12b to isolate them from the select gate 14. Accordingly, the insulator materials 18, 20, 22 will isolate the first and second memory gates 12a, 12b from the diffusion regions 16a, 16b and the select gate 14.

FIG. 4 further shows the select gate 14 formed underneath the first memory gate 12a and the second memory gate 12b, and isolated from the semiconductor material 16 by insulator material 24, e.g., oxide on sidewalls and bottom surface of the trench of the semiconductor material 16. The remaining features of the structure 10c are similar to the structure 10 of FIG. 1 such that no further explanation is required for a complete understanding of the present disclosure.

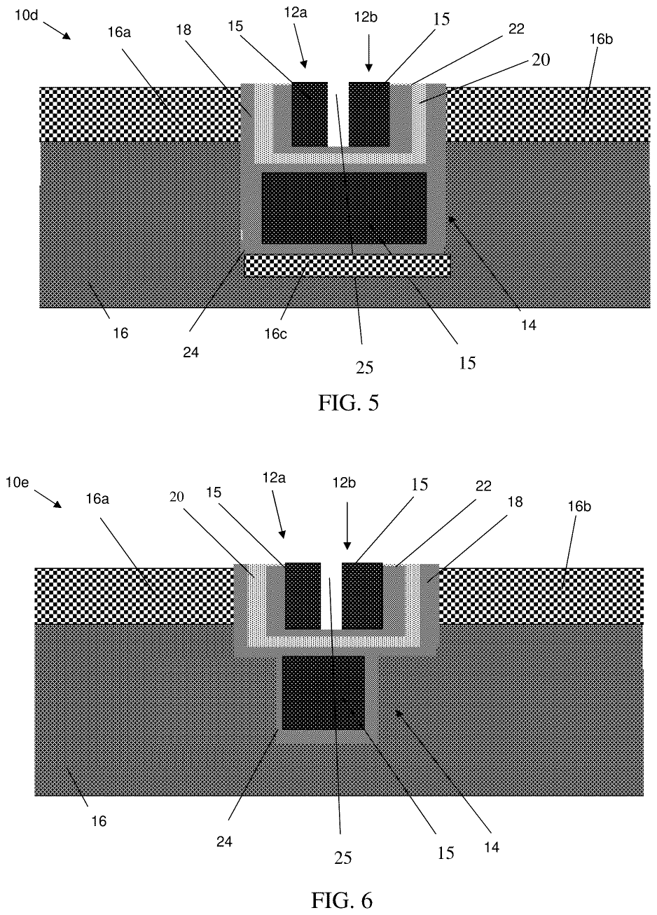

In FIG. 5, the structure 10d includes a diffusion region 16c underneath the select gate 14 within the semiconductor substrate 16, similar to the structure shown in FIG. 4. In this embodiment, the diffusion region 16c may be an n+diffusion region separated from the polysilicon 15 of the select gate 14 by the insulator material 24. The remaining features of the structure 10d are similar to the structure 10c of FIG. 4 such that no further explanation is required for a complete understanding of the present disclosure.

In FIG. 6, the structure 10e includes the first memory gate 12a and the second memory gate 12b over the select gate 14, each of which are embedded within the semiconductor substrate 16 as described with respect to FIG. 5. In this embodiment, though, a width of the select gate 14 may be smaller than a combination of the first memory gate 12a, the second memory gate 12b and the airgap 25. The remaining features of the structure 10e are similar to the structure 10d of FIG. 5 such that no further explanation is required for a complete understanding of the present disclosure.

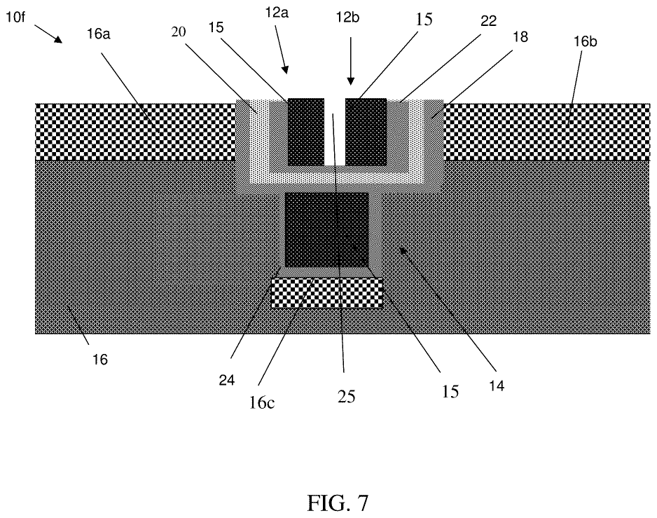

In FIG. 7, the structure 10f includes a diffusion region 16c underneath the select gate 14 within the semiconductor substrate 16 as shown in the structure 10e of FIG. 6. Again, the diffusion region 16c may be an n+diffusion region separated from the polysilicon 15 of the select gate 14 by the insulator material 24. The remaining features of the structure 10f are similar to the structure 10e of FIG. 6 such that no further explanation is required for a complete understanding of the present disclosure.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor substrate;
a plurality of memory gates isolated from the semiconductor substrate by a stack of insulator materials; and
a select gate embedded within the semiconductor substrate and shared with the plurality of memory gates.

2. The structure of claim 1, further comprising diffusion regions in the semiconductor substrate, the plurality of memory gates being isolated from the diffusion regions and the semiconductor material by the stack of insulator materials.

3. The structure of claim 2, wherein the stack of insulator materials comprises nitride material sandwiched between oxide material.

4. The structure of claim 2, wherein the select gate is below a surface of the semiconductor material and is isolated from the semiconductor material and the plurality of memory gates by an insulator layer surrounding the select gate.

5. The structure of claim 2, wherein the plurality of memory gates comprise two memory gates embedded within the semiconductor and laterally aligned with the select gate which is between the two memory gates.

6. The structure of claim 2, wherein the plurality of memory gates are above the semiconductor substrate and are isolated from the semiconductor substrate by the stack of insulator materials.

7. The structure of claim 6, wherein the select gate is isolated from the semiconductor substrate by an insulator layer on sidewalls and a bottom of the select gate.

8. The structure of claim 6, further comprising a diffusion region within the semiconductor substrate and below the select gate, the diffusion region being isolated from the select gate by the insulator layer.

9. The structure of claim 1, wherein the plurality of memory gates are embedded within the semiconductor substrate and vertically aligned with the select gate.

10. The structure of claim 1, wherein the plurality of memory gates are above the select gate and separated from diffusion regions and the select gate by the stack of insulator materials.

11. The structure of claim 10, wherein the plurality of memory gates are laterally spaced apart and are vertically aligned with the select gate.

12. The structure of claim 11, further comprising a diffusion region within the semiconductor substrate below the select gate, the diffusion region being isolated from the select gate by an insulator layer on a bottom surface of the select gate.

13. The structure of claim 10, wherein the plurality of memory gates and space therebetween have a combined width which is one of a same and smaller than the select gate.

14. A structure comprising:
a semiconductor substrate comprising diffusion regions;
a plurality of memory gates between the diffusion regions and isolated from the semiconductor substrate by a stack of insulator materials; and
a select gate shared amongst the plurality of memory gates and within the semiconductor substrate.

15. The structure of claim 14, wherein the plurality of memory gates and the select gate are laterally aligned with one another and are embedded with the semiconductor substrate.

16. The structure of claim 15, wherein the plurality of memory gates are isolated from the semiconductor substrate by oxide, nitride and oxide on an outer sidewall and a bottom surface of the plurality of memory gates, and the select gate is isolated from the semiconductor substrate and the plurality of memory gates by an insulator layer surrounding the select gate.

17. The structure of claim 14, wherein the plurality of memory gates are above the semiconductor substrate and the select gate, the plurality of memory gates are isolated from the semiconductor substrate by oxide, nitride and oxide on a bottom surface of the plurality of memory gates, and the select gate is isolated from the semiconductor substrate by an insulator layer surrounding the select gate.

18. The structure of claim 14, wherein the plurality of memory gates are above the semiconductor substrate and the select gate, the plurality of memory gates and select gate are vertically aligned, and the plurality of memory gates are isolated from the semiconductor substrate and the select gate by oxide, nitride and oxide on a bottom surface of the plurality of memory gates and an outer sidewall.

19. The structure of claim 18, wherein the plurality of memory gates are spaced apart from one another.

20. A method comprises:
forming a plurality of memory gates isolated from a semiconductor substrate by a stack of insulator materials; and
forming a select gate embedded within the semiconductor substrate and shared with the plurality of memory gates.
